(19) United States
(12) Patent Application Publication
(10) Pub. No.: US 2026/0165109 A1
(43) Pub. Date: Jun. 11, 2026

(54) DIRECT BACKSIDE POWER DELIVERY SYSTEM FOR STACKED CHIPS

(71) Applicant: INTERNATIONAL BUSINESS MACHINES CORPORATION, ARMONK, NY (US)

(72) Inventors: Xiaoli He, Clifton Park, NY (US); Joshua Mark Rubin, Albany, NY (US); Tao Li, Slingerlands, NY (US); Ruilong Xie, Niskayuna, NY (US)

(21) Appl. No.: 18/969,799

(22) Filed: Dec. 5, 2024

(51) Int. Cl. H01L 23/528; H01L 23/522; H01L 25/07

(52) U.S. Cl. CPC H10W 20/427; H10W 20/42; H10W 20/435; H10W 90/00; H10W 90/297

(57) ABSTRACT

Embodiments disclosed herein include a semiconductor structure. The semiconductor structure may include a first die, and a second die bonded above the first die. The second die may include a front-end-of-line (FEOL) on a bottom side of the second die facing the first die and a backside power delivery network (BSPDN) on a top side of the second die. The semiconductor structure may also include a permanent carrier hybrid bonded above the second die with a power grid directly supplying a power signal to the BSPDN.

### BACKGROUND

The present invention relates generally to the field of semiconductor device manufacturing, and more particularly to powering a chip stack.

Stacked semiconductor chips vertically integrate multiple layers of integrated circuits into a single package. Integration in this manner contrasts with some traditional integrated circuits, where components are spread out on a single plane. Key technologies enabling this include through-silicon vias, which provide vertical electrical connections, and wafer-level packaging, which packages integrated circuits at the wafer level before they are cut into individual chips.

The advantages of stacked chips are significant. For example, stacked chips can provide improved performance from reduced signal distance, faster processing speeds, lower power consumption, and a smaller physical footprint. By integrating memory and logic type chips into a single package, stacked chips may further enhance overall system performance and functionality.

### SUMMARY

Aspects of an embodiment of the present invention include a semiconductor structure. The semiconductor structure may include a first die, and a second die bonded above the first die. The second die may include a front-end-of-line (FEOL) on a bottom side of the second die facing the first die and a backside power delivery network (BSPDN) on a top side of the second die. The semiconductor structure may also include a permanent carrier hybrid bonded above the second die with a power grid directly supplying a power signal to the BSPDN.

Aspects of an embodiment of the present invention encompass a method of fabricating a semiconductor structure. The method may include bonding a second die above a first die. The second die including a front-end-of-line (FEOL) on a bottom side of the second die facing the first die and a backside power delivery network (BSPDN) on a top side of the second die. The method may also include hybrid bonding a permanent carrier above the second die. The permanent carrier may include a power grid directly supplying a power signal to the BSPDN.

Aspects of an embodiment of the present invention include a semiconductor structure. The semiconductor structure may include a permanent carrier with a power grid and a chip stack. An upper die of the chip stack may include a backside power delivery network (BSPDN) on a top side. The power grid may directly supply a power signal to the BSPDN.

### BRIEF DESCRIPTION OF THE DRAWINGS

FIG. 1 depicts a cross-sectional side view of a semiconductor structure, in accordance with one embodiment of the present invention.

FIG. 2 depicts a cross-sectional side view of a second die, in accordance with one embodiment of the present invention.

FIGS. 3A-3C illustrate a method of packaging a die for use as a hybrid-bonded wafer in wafer-to-wafer packaging.

FIGS. 4A-4D illustrate a method of packaging a die for use as a hybrid-bonded wafer in wafer-to-wafer packaging.

FIG. 5 depicts a cross-sectional side view of a semiconductor structure at a stage of fabrication, in accordance with one embodiment of the present invention.

FIGS. 6A and 6B show a chip-to-wafer packaging process of forming a semiconductor structure, which may also be used with a permanent carrier directly supplying a power signal to a BSPDN on a top die in a chip stack.

FIGS. 7A-7D show a chip-to-chip packaging process of forming a semiconductor structure, which may also be used with a permanent carrier directly supplying a power signal to a BSPDN on a top die in a chip stack.

### DETAILED DESCRIPTION

In the following detailed description, reference is made to the accompanying drawings, which show specific examples of embodiments of the invention. These embodiments are described in sufficient detail to enable those skilled in the art to practice them, and it is to be understood that other embodiments may be utilized, and that structural, logical, and electrical changes may be made without departing from the described embodiments. The following detailed description is, therefore, not to be taken in a limiting sense, and the included embodiments are defined by the appended claims.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

References in the specification to “one embodiment,” “an embodiment,” “certain embodiments,” etc., indicate that the embodiment described may include a particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “right,” “left,” “vertical,” “horizontal,” “top,” “bottom,” and derivatives thereof shall relate to the disclosed structures and methods, as oriented in the drawing Figures. The terms “above,” “below,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

It will be understood that when an element as a layer, region or substrate is referred to as being “on” or “over” another element, it can be directly on the other element or intervening elements may also be present. In contrast, when an element is referred to as being “directly adjacent,” “directly on,” or “directly over” another element, there are no intervening elements present. It will also be understood that when an element is referred to as being “beneath” or “under” another element, it can be directly below or under the other element, or intervening elements may be present. Additionally, when an element is referred to as being “directly below” or “directly above” another element, intervening elements may be present, but the elements overlap at least partially relative to a vertical axis perpendicular to a major surface. With regard to the fabrication of transistors and integrated circuits, major surface refers to that surface of the semiconductor layer in and about which a plurality of transistors are fabricated, e.g., in a planar process. As used herein, the term “vertical” means substantially orthogonal with respect to the major surface and “horizontal” means substantially parallel to the major surface. Typically, the major surface is along a plane of a monocrystalline silicon layer on which transistor devices are fabricated. Each reference number may refer to an item individually or collectively as a group. For example, a chip stack 102 may refer to a single chip stack 102 or multiple chip stacks 102.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. In some embodiments, epitaxial growth and/or deposition processes can be selective to forming on semiconductor surfaces, and may or may not deposit material on other exposed surfaces, such as silicon dioxide or silicon nitride surfaces.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used, and structural or logical changes may be made, without departing from the spirit and scope defined by the claims. The description of the embodiments is not limiting. In particular, elements of the embodiments described hereinafter may be combined with elements of different embodiments. Additionally, layers may be shown herein as homogeneous structures when in fact these layers are formed in multiple layering steps. These multiple steps may include the same or similar materials deposited multiple times, or may include different materials with similar properties (e.g., insulative or conductive properties) deposited multiple times to form the structure(s) depicted below.

In some embodiments, etching mask layer(s) may be provided, and the layers that are not protected thereby are removed. For example, as is understood in the art, a mask layer, sometimes referred to as a photomask, may be provided by forming a layer of photoresist material on another layer, exposing the photoresist material to a pattern of light, and developing the exposed photoresist material. An etching process, such as a reactive ion etch (RIE), may be used to form patterns (e.g., openings) by removing portions of another layer. After etching, the mask layer may be removed using a conventional plasma ashing or stripping process. Accordingly, the pattern of the mask layer facilitates the removal of another layer, such as an amorphous SiO2 layer and/or a conductive oxide diffusion barrier, for example, in areas where the mask layer has not been deposited.

For the sake of brevity, conventional techniques related to semiconductor structure and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor structures and semiconductor-based ICs are well known and so, in the interest of brevity, many conventional steps will only be mentioned briefly herein or will be omitted entirely without providing the well-known process details.

Improvements in the design of integrated circuits (IC) have enabled feature sizes for transistors in a device layer to enter into deep submicron and nanometer regime. Embodiments herein recognize benefits from stacking ICs and providing power directly to the top stacked chip rather than powering the backside power delivery network (BSPDN) through the chip using vias. Stacked chips also present challenges semiconductor fabrication. Managing heat dissipation in stacked configurations is more complex than in traditional designs, and the manufacturing processes involved are more intricate and may employ a higher degree of precision.

Embodiments disclosed herein, therefore, include semiconductor structures with a permanent carrier directly supplying a power signal to the BSPDN. Directly supplying a power signal, in this application, means that the power signal does not pass through a chip stack, or through an individual chip in the stack, but directly contacts the BSPDN in the top chip from a top side. The permanent carrier may receive the power signal from a wafer or power connection on the bottom of the chip stack, but the delivery to the BSPDN is directly supplied by connections from the permanent carrier to the BSPDN.

In some aspects, the techniques described herein relate to a semiconductor structure, including: a first die; a second die bonded above the first die, including: a front-end-of-line (FEOL) on a bottom side of the second die facing the first die; and a backside power delivery network (BSPDN) on a top side of the second die. The division of the FEOL and the BSPDN provides the technical benefit of increased density and efficient space and signal routing. The semiconductor structure may also include a permanent carrier hybrid bonded above the second die including a power grid directly supplying a power signal to the BSPDN. The permanent carrier provides the technical benefit of efficient delivery of power to the semiconductor structure, which in turn can lead to better heat dissipation and greater efficiency in powering the BSPDN.

In some aspects, the techniques described herein relate to a semiconductor structure, further including a tall through via adjacent to and insulated from the first die and the second die, wherein the tall through via supplies the power signal to the power grid. In some aspects, the techniques described herein relate to a semiconductor structure, further including a through via stack adjacent to and insulated from the first die and the second die, wherein the through via stack supplies the power signal to the power grid. In some aspects, the techniques described herein relate to a semiconductor structure, wherein the through via stack includes a first through via adjacent to the first die, and a second through via adjacent to the second die. The tall through via and via stack provide the technical benefit of powering the BSPDN without taking up space within the semiconductor structure.

In some aspects, the techniques described herein relate to a semiconductor structure, further including redistribution layers formed on the BSPDN below the permanent carrier. The redistribution layers provide the technical benefit of accurate and secure connection between the BSPDN and the permanent carrier by fabricating layers directly on the BSPDN or the permanent carrier and forming bonding structures that will ensure secure connection when the permanent carrier is bonded to the chip stack. In some aspects, the techniques described herein relate to a semiconductor structure, wherein the redistribution layers provide power to the BSPDN independent of the permanent carrier. These redistribution layers provide the technical benefit of powering the BSPDN even if the permanent carrier suffers a defect.

In some aspects, the techniques described herein relate to a semiconductor structure, wherein the first die is hybrid bonded to the second die. This bonding provides the technical benefit of simultaneous fabrication of the first die and the second die, which improves the speed of fabrication, and lowers the chance of defects by reducing the fabrication steps required to build the chip stack.

In some aspects, the techniques described herein relate to a semiconductor structure, further including a wafer connected to a bottom of the first die. The wafer provides the technical benefits of connecting the chip stack to known and conventional structures such that known and conventional signals can be used by and produced from the chip stack and the semiconductor structure generally.

In some aspects, the techniques described herein relate to a semiconductor structure, wherein the first die includes a first-die BSPDN located at a selection from the group consisting of: a top side of the first die and a bottom side of the first die. The first-die BSPDN being located on either side of the first die provides the technical benefit of flexible incorporation and adoption of the first die into known chip design, or in other words provides the opportunity for the first die to be adopted in a wide variety of integrated circuits.

In some aspects, the techniques described herein relate to a method of fabricating a semiconductor structure, including: bonding a second die above a first die, wherein the second die includes: a front-end-of-line (FEOL) on a bottom side of the second die facing the first die; and a backside power delivery network (BSPDN) on a top side of the second die; and hybrid bonding a permanent carrier above the second die, wherein the permanent carrier includes a power grid directly supplying a power signal to the BSPDN. The permanent carrier provides the technical benefit of efficient delivery of power to the semiconductor structure, which in turn can lead to better heat dissipation and greater efficiency in powering the BSPDN.

In some aspects, the techniques described herein relate to a semiconductor structure, including: a permanent carrier including a power grid; a chip stack, wherein an upper die includes a backside power delivery network (BSPDN) on a top side; and wherein the power grid is directly supplying a power signal to the BSPDN. The permanent carrier provides the technical benefit of efficient delivery of power to the semiconductor structure, which in turn can lead to better heat dissipation and greater efficiency in powering the BSPDN.

In some aspects, the techniques described herein relate to a semiconductor structure, wherein the BSPDN includes a thick VDD plate, a thick VSS plate, and a high-κ interlayer dielectric. The thick VDD plate and the thick VSS plate provide the technical benefit of simplified fabrication, since each may be formed as a single layer rather than a grid of many layers with interconnects. The VDD and VSS plates also take advantage of the increased heat dissipation from the permanent carrier without suffering damage due to the potentially high currents in the plates.

The present invention and an example fabrication process will now be described in detail with reference to the Figures.

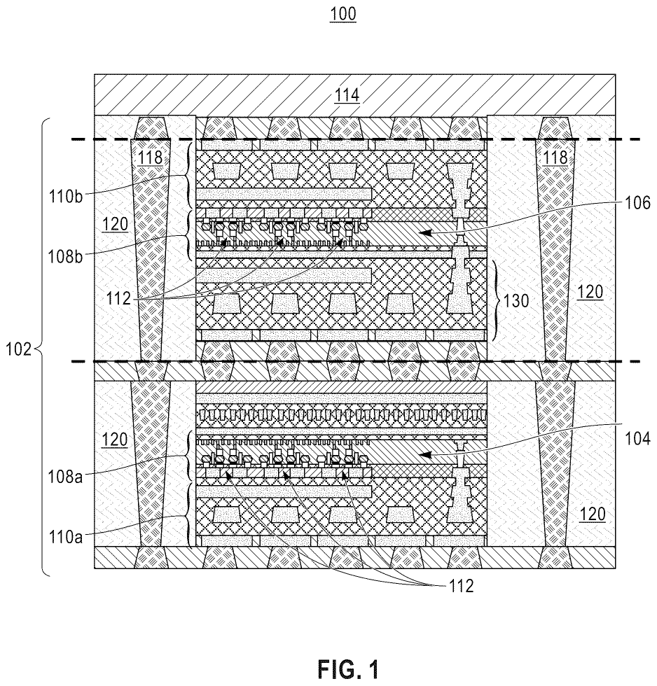

FIG. 1 depicts a cross-sectional side view of a semiconductor structure 100, in accordance with one embodiment of the present invention. The semiconductor structure 100 includes a chip stack 102 with a first (bottom, lower) die 104 and a second (upper, top) die 106 bonded above the first die 104. In the illustrated embodiment, the first die 104 includes a front-end-of-line (FEOL) 108a and a backside power delivery network (BSPDN) 110a. Similarly, the second die 106 includes a FEOL 108b and a BSPDN 110b. The FEOLs 108a, b include field-effect transistor (FET) devices 112 that are connected by rows and columns of connecting structures organized in metal layers.

The metal layers may collectively be called middle-of-line (MOL) layers or back-end-of-line (BEOL) layers 130. The BEOL 130 connects the FEOL 108 to external power and communication sources, and includes many (e.g., dozens) of layers of wires, vias, and connects. The BEOL layers 130 are formed by first depositing insulating materials (typically silicon dioxide or low-k dielectrics) on top of the FEOL 108, then using lithography and etching techniques to define patterns for metal interconnects and vias in this insulating layer. Subsequently, metal layers (commonly aluminum or copper) are deposited, and further lithography and etching steps are employed to shape these layers into interconnects and vias. This process is repeated to build multiple layers of insulating materials, metal interconnects, and vias as needed for the specific semiconductor technology and device, ultimately finishing with a top insulating layer that serves to protect the metal interconnects and complete the BEOL 130.

The semiconductor structure 100 also includes a permanent carrier 114 on the top of the chip stack 102. The second die 106 receives a power signal directly from the permanent carrier 114 into the BSPDN 110b, and therefore the BSPDN 110b is located on the top side of the second die 106. The first die 104, on the other hand, when stacked with the second die 106 may be fabricated without the BSPDN 110a. In embodiments that do have a BSPDN 110a, the BSPDN 110a is located so that the power signal may come from the primary power delivery source from the bottom of the overall packaging of the semiconductor structure 100. In certain embodiments without the BSPDN 110a, the first die 104 may have the FEOL 104a face either up or down, with the connecting structures on either the bottom or the top.

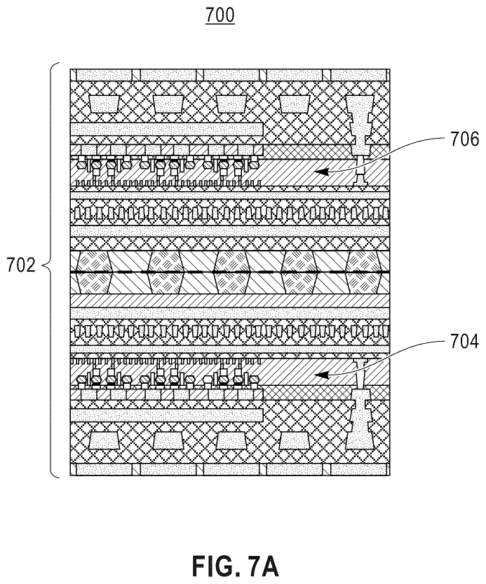

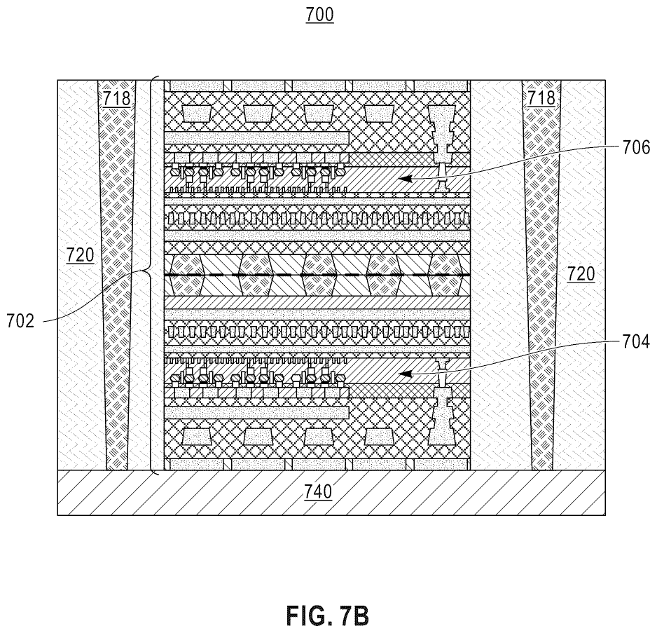

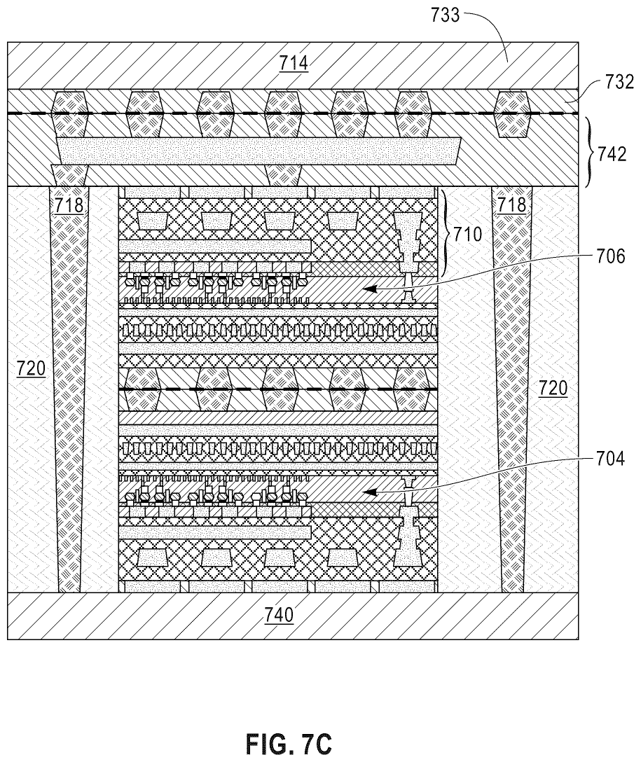

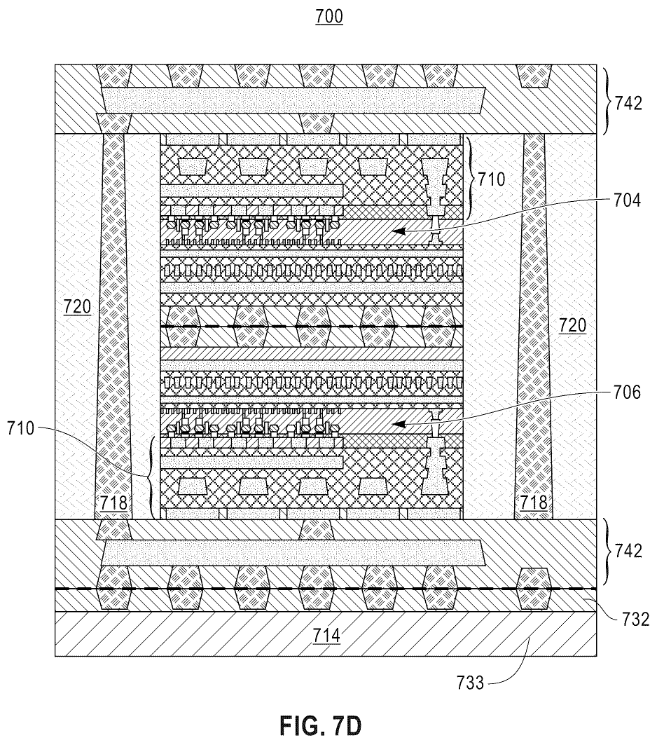

While the semiconductor structure 100 and the overall packaging receives power from the bottom, the semiconductor structure 100 includes through vias 118 that convey the power signal from the bottom of the semiconductor structure 100 to the permanent carrier 114 on the top. That is, the first die 104 and the second die 106 may receive power through multiple delivery methods. A first power delivery method includes a standard 3-dimensional power delivery through the chip stack 102. The actual BEOL 130, FEOL 108b, and BSPDN 110b may include power delivery structures that are bonded to the first die 104 and receive power therethrough. A second power delivery method is described in significantly more detail below, and includes the second die 106 getting power only from above via the permanent carrier 114 or redistribution layers (e.g., redistribution layers 742 in FIG. 7C).

The through vias 118 may include a via stack (as pictured in FIG. 1) or may include tall vias or other conductive via structures conveying the power signal. The through vias 118 may be located adjacent to the chip stack 102, or may be located away (i.e., separated and insulated) from the chip stack 102 elsewhere in the semiconductor structure 100. The through vias 118 are insulated from the chip stack 102 by a dielectric fill material 120. The direction in which the narrow end of the through vias 118 is pointing (i.e., down in FIG. 1) is dependent on the direction in which the through via holes are etched. In certain embodiments, the through via holes (and thus the through vias 118) may be formed from the bottom, in which case the narrow end of the through vias 118 would be at the top of the first die 104 and the second die 106.

As explained in detail below, the chip stack 102 and the semiconductor structure 100 in general may be fabricated through a variety of methods: die to die, die to wafer, wafer to wafer packaging, for example.

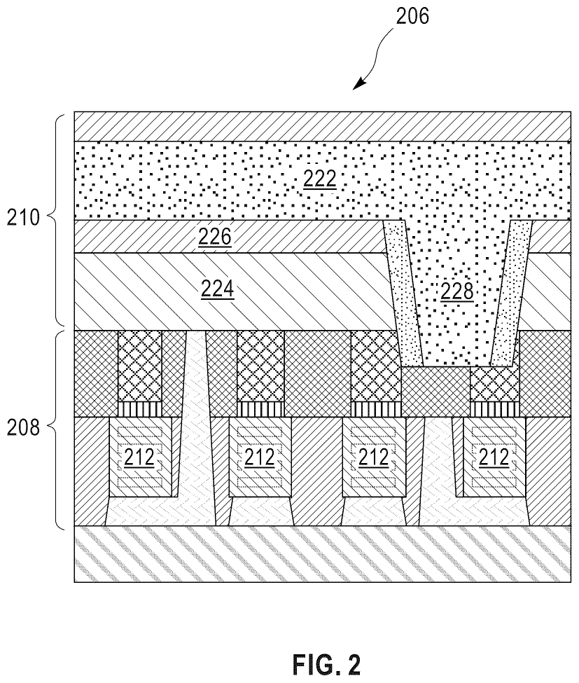

FIG. 2 depicts a cross-sectional side view of a second die 206, in accordance with one embodiment of the present invention. The second die 206 includes a FEOL 208 and a BSPDN 210 conveying power signals to FET device 212. The BSPDN 210 of FIG. 2 has thick plates for powering FET devices 212: a VSS plate 222 and a VDD plate 224 separated by high-κ interlayer dielectric (ILD) 226. The VDD plate 224 is directly connect to contacts for the FET device 212, while the VSS plate 222 utilizes dielectric-lined passthrough vias 228 that convey the power signal through the VDD plate 224 to the contacts of the FET device 212. FIG. 1 (and the remaining Figures of the description below) illustrates a more traditional metal-layered BSPDN, but the BSPDN 210 in this embodiment of FIG. 2 may benefit from the better thermal dissipation of the permanent carrier described herein. The ILD 226 is also formulated to improve the thermal dissipation that may accompany the design of the dual-plate BSPDN 210. The second die 206 of FIG. 2 may be swapped for the second die of any other embodiment described in this application.

The remaining figures below will be used to describe fabrication methods for semiconductor structures that directly power a BSPDN in a top die of a chip stack.

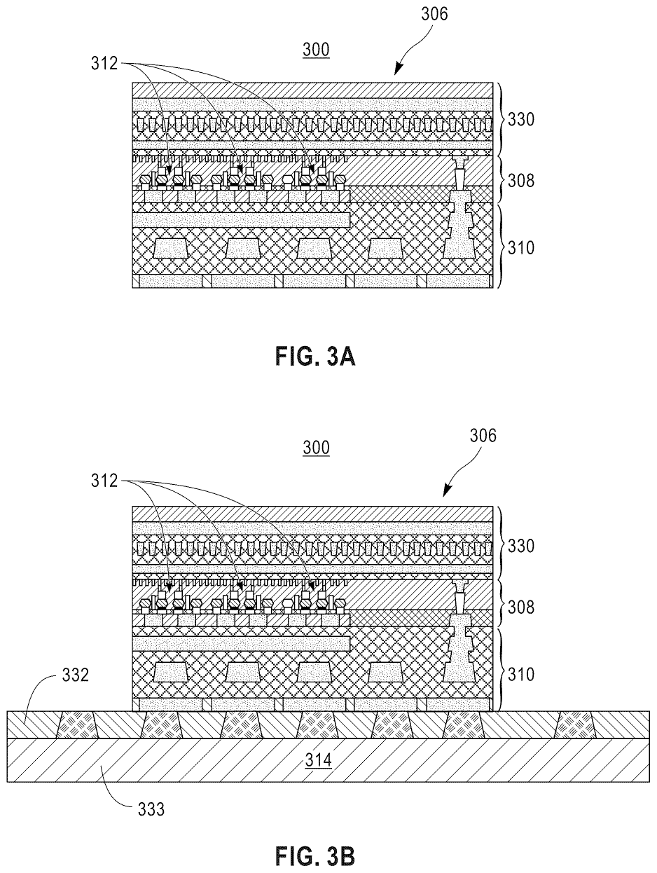

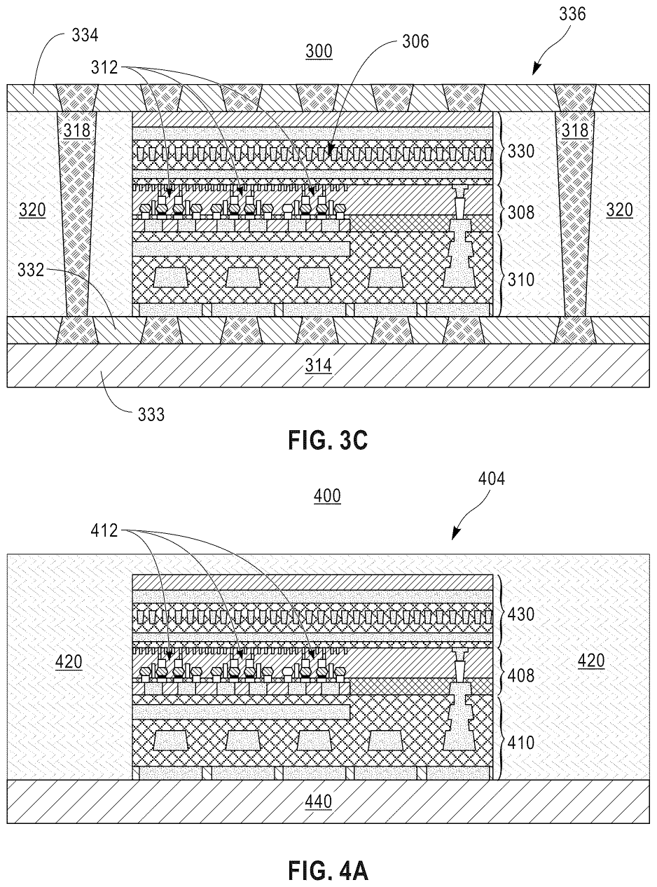

FIGS. 3A-3C illustrate a method of packaging a die for use as a hybrid-bonded wafer in wafer-to-wafer packaging. FIG. 3A depicts a cross-sectional side view of a semiconductor structure 300, in accordance with one embodiment of the present invention. The semiconductor structure 300 includes a second die 306 with a FEOL 308 that may be fabricated using known techniques such as deposition, growth, lithographic patterning, and etch processes that build up layers for FET devices 312, and metal connecting layers in a BEOL 330. The illustrated die is labeled “second die” (without a “first die”) due to the intention to use the die, and the wafer in which the second die is packaged, as the top die in chip stacks such as the chip stack 102 illustrated in FIG. 1.

The second die 306 is typically formed on a substrate that may be made of dielectric materials (e.g., silicon nitride (SiN), silicon boron carbon nitride (SiBCN), silicon oxygen carbon nitride, (SiOCN), silicon oxygen carbide (SiOC)). After the fabrication of the FEOL 308 and the BEOL 330, the second die 306 may be flipped over for fabrication of a BSPDN 310. The second die 306 is not shown to scale, and in particular the number and size of layers in the BEOL 330 and the BSPDN 310 may vary in various embodiments.

FIG. 3B depicts a cross-sectional side view of the semiconductor structure 300 of FIG. 3A at a subsequent stage in fabrication, in accordance with one embodiment of the present invention. The semiconductor structure 300 includes a permanent carrier 314 hybrid bonded with the BSPDN 310 of the second die 306. Several dies may be hybrid bonded to the permanent carrier. Hybrid bonding is a semiconductor fabrication technique that connects multiple chips or wafers by bonding them face-to-face using copper pads surrounded by silicon oxide. This method allows for higher interconnect density, improved performance due to reduced signal delay and energy consumption, and greater flexibility in integrating chips from different nodes and even different fabrication locations and/or techniques. The hybrid bonding techniques used to attach the second die 306 to the permanent carrier 314 enhance performance and density of the semiconductor structure 300, especially in comparison to traditional transistor scaling. The permanent carrier 314 may include one or more c-power delivery network (c-PDN) layers 332 that are fabricated on the permanent carrier before hybrid bonding to the BSPDN 310. The c-PDN layers 332 may be used, for example, to bridge any difference in size between the outer layers of the BSPDN 310 and the smaller dimensions of a power grid 333 of the permanent carrier 314. With the c-PDN layers 332, the hybrid bonding will result in an accurate and secure connection, with each power signal delivered to the correct line in the BSPDN 310.

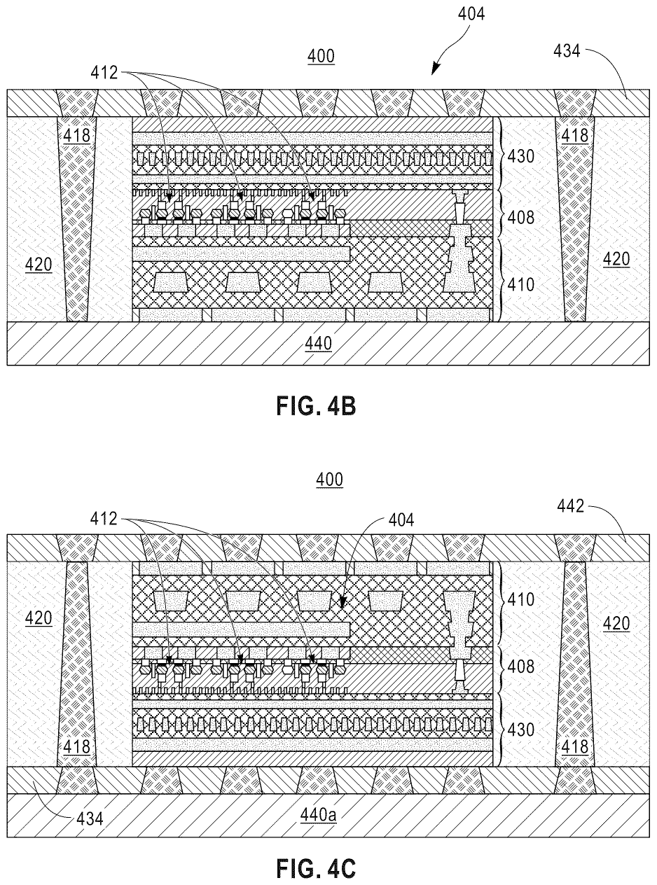

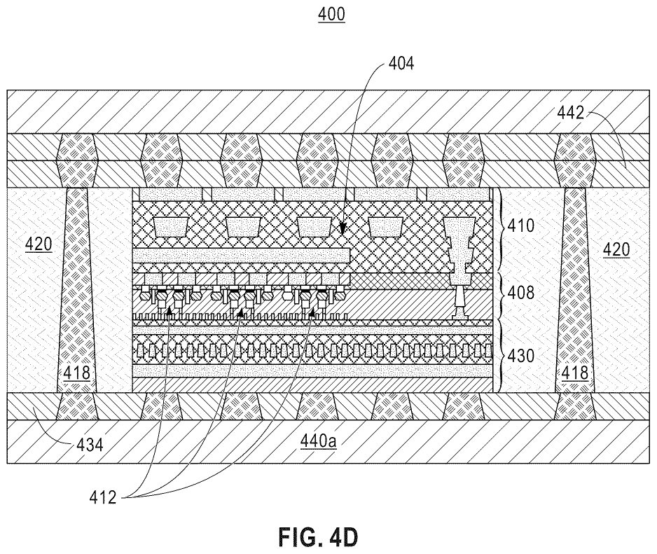

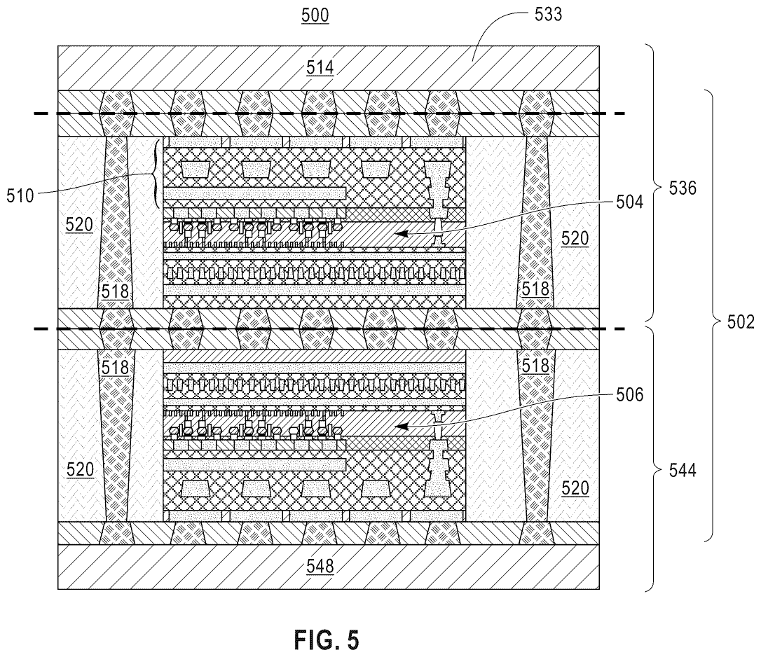

FIG. 3C depicts a cross-sectional side view of a semiconductor structure 300 at a subsequent stage of fabrication, in accordance with one embodiment of the present invention. The semiconductor structure 300 includes a dielectric fill material 320 deposited around the second die 306, with through vias holes etched and filled (i.e., with conductive material such as metal) to form the through vias 318. After the through vias 318 are formed, a metal connection layer 334 may be fabricated on top of the FEOL 308. The metal connection layer 334 constitutes the finishing touch on a top wafer 336 that enables the second die 306 (and any other dies bonded to the permanent carrier 314) to be hybrid bonded to another wafer (e.g., reconstituted wafer formed through the process illustrated in FIGS. 4A-4C), as explained in detail with reference to FIG. 5 below.

FIG. 4A depicts a cross-sectional side view of a semiconductor structure 400, in accordance with one embodiment of the present invention. The semiconductor structure 400 includes a first die 404, that may be used as either the bottom die or the top die in a chip stack. The first die 404 may be fabricated similarly to the second die 306 described above. In fact, the first die 404 could be fabricated as part of the same wafer, which is then diced into separate dies for bonding on a wafer. Unlike the second die 306 described above, however, the first die 404 is not hybrid bonded immediately to a permanent carrier, but is instead temporarily bonded to a temporary carrier 440 and surrounded by a deposition of dielectric fill material 420.

FIG. 4B depicts a cross-sectional side view of the semiconductor structure 400 of FIG. 4A at a subsequent stage of fabrication, in accordance with one embodiment of the present invention. The semiconductor structure 400 includes through vias 418 etched and metalized through the dielectric fill material 420 and a metal connection layer 434 fabricated on the top surface of the first die 404. The metal connection layer 434 includes metal connections in rows or columns that match with the contacts of the BEOL 430, so that the control signals may be passed to and from the FET devices 412 to the metal connection layer 434.

FIG. 4C depicts a cross-sectional side view of the semiconductor structure 400 of FIG. 4A at a subsequent stage of fabrication, in accordance with one embodiment of the present invention. The semiconductor structure 400 includes a second temporary carrier 440a attached on the bottom of the first die 404 and a redistribution layer 442 fabricated on the BSPDN 410. The redistribution layer 442 is typically fabricated after the first die 404 is flipped over so that the FEOL 408 and the BEOL 430 are on the bottom and the BSPDN 410 is on the top. The semiconductor structure 400 at this stage may be used as a reconstituted wafer 444 for wafer-to-wafer bonding into a chip stack. The reconstituted wafer 444 at this stage would be used as the bottom die in the chip stack. Alternatively, the reconstituted wafer 444 may continue through the process (e.g., illustrated in FIG. 4D), enabling use as a top wafer in the chip stack.

FIG. 4D depicts a cross-sectional side view of the semiconductor structure 400 of FIG. 4A at a subsequent stage of fabrication, in accordance with one embodiment of the present invention. The semiconductor structure 400 includes a permanent carrier 414 hybrid bonded to the BSPDN 410. The permanent carrier 414 is fabricated with a power grid and also may include a c-PDN layer 432 to accurately match the redistribution layer 442 according to the size and orientation of the metal connects. As with the wafer formed through the process illustrated in FIGS. 3A-3C, the semiconductor structure 400 in FIG. 4D may be formed with several dies on the same wafer. A hybrid-bonded wafer 446 formed in this manner may be ready to form into a chip stack.

FIG. 5 depicts a cross-sectional side view of a semiconductor structure 500 at a stage of fabrication, in accordance with one embodiment of the present invention. The semiconductor structure 500 includes a top wafer 536 and a reconstituted wafer 544 hybrid bonded together to form a chip stack 502 of a first die 504 and a second die 506. The semiconductor structure 500 also includes a permanent carrier 514 that is hybrid bonded to the top wafer 536 in the manner described above. The permanent carrier 514 includes a power grid 533 that directly powers a BSPDN 510 in the second die 506. Since the semiconductor structure 500 was formed through wafer-to-wafer packaging, the power grid 533 is powered by a via stack of through vias 518 that convey a power signal through a dielectric fill material 520 from a package wafer 548 that is at the bottom of the semiconductor structure 500. In this manner, the BSPDN 510 of the second die 506 can be directly powered even when the BSPDN 510 is at the top of the chip stack 502.

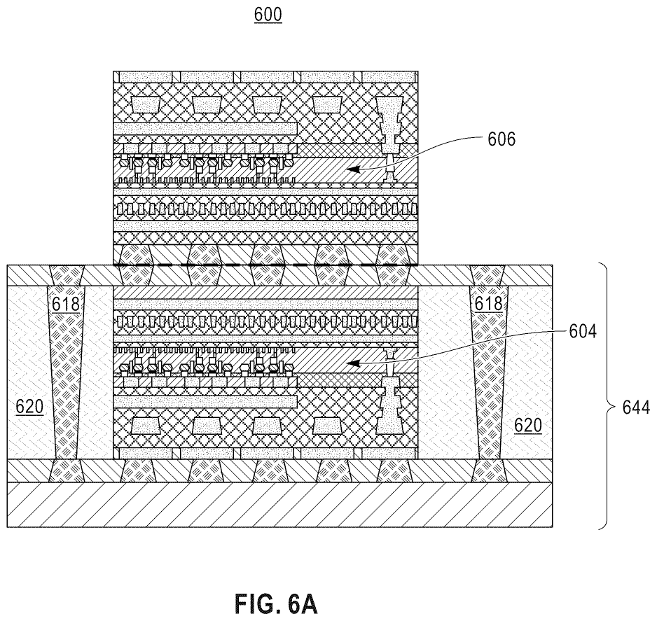

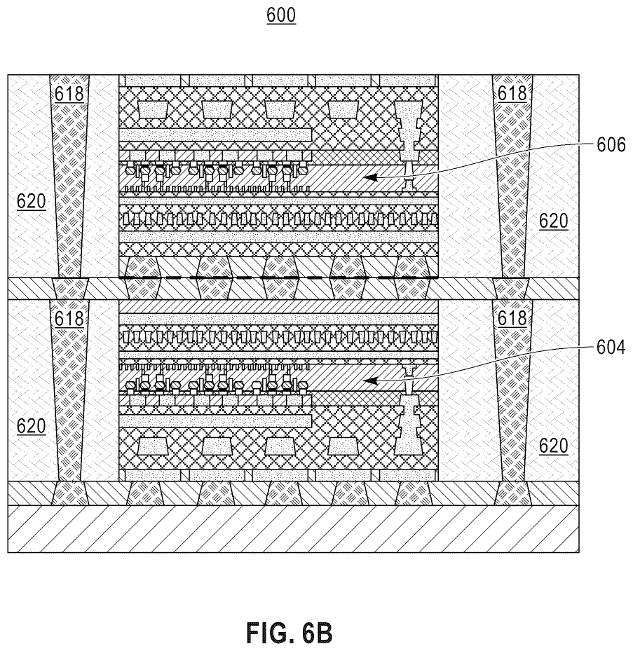

FIGS. 6A and 6B show a chip-to-wafer packaging process of forming a semiconductor structure, which may also be used with a permanent carrier directly supplying a power signal to a BSPDN on a top die in a chip stack. FIG. 6A depicts a cross-sectional side view of a semiconductor structure 600 at a stage of fabrication, in accordance with one embodiment of the present invention. The semiconductor structure 600 includes a reconstituted wafer 644 that may be fabricated, for example, through the process described in relation to FIGS. 4A-4C. Unlike the embodiment in FIG. 5, however, this embodiment of the semiconductor structure 600 has the reconstituted wafer 644 bonded to a second die 606. That is, the reconstituted wafer 644 is not bonded to a wafer, but rather a first die 604 of the reconstituted wafer 644 is bonded to the second die 606. In fact, the reconstituted wafer 644 may have a plurality of second dies 606 bonded in a similar manner and time to the illustrated second die 606.

FIG. 6B depicts a cross-sectional side view of the semiconductor structure 600 at a stage of fabrication, in accordance with one embodiment of the present invention. The semiconductor structure 600 shows that the second die 606 is surrounded by dielectric fill material 620, through which through vias holes have been etched and filled with conductive material to form through vias 618. The through vias 618 may convey a power signal to a permanent carrier that can be bonded to the top of the second die 606 as described above. The second die 606 may also have redistribution layers fabricated on top between the second die 606 and the permanent carrier. the permanent carrier may have PDN layers fabricated.

FIGS. 7A and 7B show a chip-to-chip packaging process of forming a semiconductor structure, which may also be used with a permanent carrier directly supplying a power signal to a BSPDN on a top die in a chip stack. FIG. 7A depicts a cross-sectional side view of a semiconductor structure 700 at a stage of fabrication, in accordance with one embodiment of the present invention. The semiconductor structure 700 includes a first die 704 bonded to a second die 706. The first die 704 and second die 706 may be fabricated using the deposition, growth, lithographic patterning, and etch processes described above to build up layers of devices and connecting structures. Once the first die 704 and the second die 706 are fabricated (e.g., separately, though the dies 704, 706 may be fabricated on the same wafer and then diced into separate dies), both dies 704, 706 are bonded together (e.g., hybrid bonded) to form a chip stack 702.

FIG. 7B depicts a cross-sectional side view of the semiconductor structure 700 at a stage of fabrication, in accordance with one embodiment of the present invention. The semiconductor structure 700 includes the chip stack 702 attached to a temporary carrier 740, after which dielectric fill material 720 is filled around the chip stack 702. The dielectric fill material 720 fills the full height of the chip stack 702 since the first die 704 and the second die 706 do not have any intermediate wafer formation that requires partial dielectric fill around one or the other of the dies 704, 706. The full height dielectric fill material 720 also enables tall through vias 718 that are etched through the full height of the chip stack 702.

FIG. 7C depicts a cross-sectional side view of the semiconductor structure 700 at a stage of fabrication, in accordance with one embodiment of the present invention. The semiconductor structure 700 includes a permanent carrier 714 hybrid bonded to the top of the chip stack 702. The semiconductor structure 700 also includes optional redistribution layers 742 formed on the top of the chip stack 702 before the permanent carrier 714 is bonded. The redistribution layers 742 convey a power signal from the permanent carrier 714 (and an embedded power grid 733) directly to a BSPDN 710 in the second die 706. The permanent carrier 714 also shows an optional PDN layer 732 that is fabricated on the permanent carrier 714 before bonding to the chip stack 702.

FIG. 7D depicts a cross-sectional side view of the semiconductor structure 700 at a stage of fabrication, in accordance with one embodiment of the present invention. The semiconductor structure 700 includes additional optional redistribution layers 742 fabricated on a “bottom” side. The semiconductor structure 700 is flipped, and the temporary carrier 740 is removed to expose the BSPDN 710 of the first die 704. Then, layers of dielectric are deposited, etched, and metalized to form conductive pathways in the redistribution layers 742. The design of the permanent carrier 714 and the power grid 733 directly supplying a power signal to the BSPDN 710 in the second die 706 provides many benefits. For example, the design enables the redistribution layers 742 to be fabricated with high thermal conductivity that improves the dissipation of heat generated by operation of the chip stack 702. Additionally, supplying the power signal directly to the BSPDN 710 enables greater freedom in the design and use of the BSPDN 710, such that useful conventional designs of the second die 706 may be used in the chip stack 702 (where the design would otherwise be unusable).

After finalizing the redistribution layers 742 on the first die 704, the semiconductor structure 700 may then be flipped back over to finish packaging procedures.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a first die;
a second die bonded above the first die, comprising:
a front-end-of-line (FEOL) on a bottom side of the second die facing the first die; and
a backside power delivery network (BSPDN) on a top side of the second die; and
a permanent carrier hybrid bonded above the second die comprising a power grid directly supplying a power signal to the BSPDN.

2. The semiconductor structure of claim 1, further comprising a tall through via adjacent to and insulated from the first die and the second die, wherein the tall through via supplies the power signal to the power grid.

3. The semiconductor structure of claim 1, further comprising a through via stack adjacent to and insulated from the first die and the second die, wherein the through via stack supplies the power signal to the power grid.

4. The semiconductor structure of claim 3, wherein the through via stack comprises a first through via adjacent to the first die, and a second through via adjacent to the second die.

5. The semiconductor structure of claim 1, further comprising redistribution layers formed on the BSPDN below the permanent carrier.

6. The semiconductor structure of claim 5, wherein the redistribution layers provide power to the BSPDN independent of the permanent carrier.

7. The semiconductor structure of claim 1, wherein the first die is hybrid bonded to the second die.

8. The semiconductor structure of claim 1, further comprising a wafer connected to a bottom of the first die.

9. The semiconductor structure of claim 1, wherein the first die comprises a first-die BSPDN located at a selection from the group consisting of: a top side of the first die and a bottom side of the first die.

10. A method of fabricating a semiconductor structure, comprising:
bonding a second die above a first die, wherein the second die comprises:
a front-end-of-line (FEOL) on a bottom side of the second die facing the first die; and
a backside power delivery network (BSPDN) on a top side of the second die; and
hybrid bonding a permanent carrier above the second die, wherein the permanent carrier comprises a power grid directly supplying a power signal to the BSPDN.

11. The method of claim 10, further comprising forming a through via stack adjacent to and insulated from the first die and the second die, wherein the through via stack supplies the power signal to the power grid.

12. The method of claim 11, wherein forming the through via stack comprises:
forming a first through via adjacent to the first die; and
forming a second through via adjacent to the second die.

13. A semiconductor structure, comprising:
a permanent carrier comprising a power grid;
a chip stack, wherein an upper die comprises a backside power delivery network (BSPDN) on a top side; and
wherein the power grid is directly supplying a power signal to the BSPDN.

14. The semiconductor structure of claim 13, wherein the BSPDN comprises a thick VDD plate, a thick VSS plate, and a high-κ interlayer dielectric.

15. The semiconductor structure of claim 13, further comprising a tall through via adjacent to and insulated from the chip stack, wherein the tall via supplies the power signal to the power grid.

16. The semiconductor structure of claim 13, further comprising a through via stack adjacent to and insulated from the chip stack, wherein the through via stack supplies the power signal to the power grid.

17. The semiconductor structure of claim 16, wherein the through via stack comprises a first through via adjacent to the upper die, and a second through via adjacent to a lower die.

18. The semiconductor structure of claim 13, further comprising redistribution layers formed on the BSPDN below the permanent carrier.

19. The semiconductor structure of claim 13, wherein the upper die comprises a hybrid bond with the chip stack.

20. The semiconductor structure of claim 13, further comprising a wafer connected to a bottom of the chip stack.
